(19) United States
(12) Patent Application Publication
(10) Pub. No.: US 2026/0305083 A1
(43) Pub. Date: Oct. 1, 2026

(54) DISPLAY DEVICE, ELECTRONIC DEVICE AND METHOD OF MANUFACTURING DISPLAY DEVICE

(71) Applicant: SAMSUNG DISPLAY CO., LTD., YONGIN-SI (KR)

(72) Inventor: Hyun Eok SHIN, YONGIN-SI (KR)

(21) Appl. No.: 19/342,795

(22) Filed: Sep. 29, 2025

(30) Foreign Application Priority Data
Mar. 31, 2025 (KR) 10-2025-0041632

(51) Int. Cl. H10K 59/124; H10K 59/12

(52) U.S. Cl. CPC H10K 59/124; H10K 59/1201

(57) ABSTRACT

A display device includes a substrate, a semiconductor layer disposed on the substrate, a first insulating layer disposed on the semiconductor layer and including a first opening, a second insulating layer disposed on the first insulating layer and including a second opening and a concave portion, a first electrode disposed on the second insulating layer, a third insulating layer disposed on the first electrode and including a pixel opening, a light-emitting layer disposed in the pixel opening, and a first conductive layer disposed in the first opening, the second opening, and the concave portion below the first electrode.

### CROSS-REFERENCE TO RELATED APPLICATIONS

This application claims priority under 35 U.S.C. § 119 to Korean Patent Application No. 10-2025-0041632, filed on Mar. 31, 2025, the disclosure of which is incorporated by reference herein in its entirety.

### TECHNICAL FIELD

Embodiments of the present disclosure relate to a display device, an electronic device including the display device, and a method of manufacturing the display device.

### DISCUSSION OF RELATED ART

A display device is a device that visually presents data. Such display devices can be employed as display units in compact products, including mobile phones and virtual reality (VR) devices, and can also be used in larger products, such as televisions.

A display device typically includes a plurality of subpixels that receive electrical signals and emit light to display images to a viewer. Each subpixel includes a light-emitting element. For example, in a light-emitting display device, each subpixel may include a light-emitting diode (LED) serving as the light-emitting element. Generally, a light-emitting display device integrates thin-film transistors and light-emitting diodes on a substrate, allowing the diodes to emit light directly without an external backlight.

### SUMMARY

Embodiments of the present disclosure provide a display device configured to prevent or reduce incomplete contact problems between conductive layers in a high-resolution display device.

According to an embodiment of the present disclosure, a display device includes a substrate, a semiconductor layer disposed on the substrate, a first insulating layer disposed on the semiconductor layer and including a first opening, a second insulating layer disposed on the first insulating layer and including a second opening and a concave portion, a first electrode disposed on the second insulating layer, a third insulating layer disposed on the first electrode and including a pixel opening, a light-emitting layer disposed in the pixel opening, and a first conductive layer disposed in the first opening, the second opening, and the concave portion below the first electrode.

In an embodiment, the first opening, the second opening, and the concave portion are filled by the first conductive layer.

In an embodiment, the first conductive layer includes copper.

In an embodiment, the display device further includes a second conductive layer disposed in the first opening.

In an embodiment, the first electrode is electrically connected to the semiconductor layer through the first conductive layer.

In an embodiment, the first conductive layer includes a first layer and a second layer disposed on the first layer, and the first layer contacts an inner wall of the second opening and an inner wall of the concave portion.

In an embodiment, the first layer includes titanium, and the second layer includes copper.

In an embodiment, the second insulating layer includes an organic layer and an inorganic layer, the organic layer is disposed on the first insulating layer, and the inorganic layer is disposed on the organic layer.

In an embodiment, the inorganic layer is disposed in the concave portion and overlaps the concave portion in a plan view.

In an embodiment, the second insulating layer includes a first region overlapping the first conductive layer in a plan view, and a second region connected to the first region, and a step difference exists between a top surface of the first region and a top surface of the second region.

In an embodiment, the top surface of the second region of the second insulating layer and a top surface of the first conductive layer form a single flat surface.

In an embodiment, the second insulating layer includes an organic layer and an inorganic layer, the top surface of the second region of the second insulating layer includes a planar top surface of the inorganic layer and a planar top surface of the organic layer, and in a plan view, the planar top surface of the inorganic layer is disposed between the planar top surface of the first conductive layer and the planar top surface of the organic layer.

In an embodiment, a depth of the first opening is at least about 1.5 micrometers.

According to an embodiment of the present disclosure, a method of manufacturing a display device includes forming a substrate, forming a semiconductor layer on the substrate, forming a first insulating layer including a first opening on the semiconductor layer, forming a first material layer including a second opening overlapping the first opening and a concave portion on the first insulating layer, forming a conductive material layer filling the first opening, the second opening, and the concave portion, and polishing a top surface of the conductive material layer and a top surface of an insulating material layer including the first material layer to be flat.

In an embodiment, forming the first material layer includes applying a first material on the first insulating layer, and exposing the first material using a photomask. The photomask includes a first portion overlapping the first opening, a second portion adjacent to the first portion, and a third portion adjacent to the second portion. The second portion is a halftone portion that allows only a portion of light to pass through the halftone portion.

In an embodiment, the second opening is formed in a region corresponding to the first portion, and the concave portion is formed in a region corresponding to the second portion.

In an embodiment, forming the conductive material layer includes plating a conductive material.

In an embodiment, the conductive material includes copper.

In an embodiment, the conductive material layer includes a first layer and a second layer disposed on the first layer, the first layer includes titanium, and the second layer includes copper.

According to an embodiment of the present disclosure, an electronic device includes a processor and a display device connected to the processor. The display device includes a substrate, a semiconductor layer disposed on the substrate, a first insulating layer disposed on the semiconductor layer and including a first opening, a second insulating layer disposed on the first insulating layer and including a second opening and a concave portion, a first electrode disposed on the second insulating layer, a third insulating layer disposed on the first electrode and including a pixel opening, a light-emitting layer disposed in the pixel opening, and a first conductive layer disposed in the second opening and the concave portion below the first electrode.

According to embodiments of the present disclosure, an incomplete contact problem between conductive layers in a high-resolution display device can be prevented, and electrical contact between an electrode of the light-emitting element and the semiconductor layer can be stably secured.

### BRIEF DESCRIPTION OF THE DRAWINGS

The above and other features of the present disclosure will become more apparent by describing in detail embodiments thereof with reference to the accompanying drawings.

FIG. 1 is a plan view of a display device according to an embodiment of the present disclosure.

FIG. 2 is a schematic cross-sectional view of a display device according to an embodiment of the present disclosure.

FIGS. 3 to 8 are schematic cross-sectional views of a display device illustrating sequential processes of a method of manufacturing a display device according to an embodiment of the present disclosure.

FIG. 9 is a schematic plan view of a display device at a process of FIG. 8 according to a method of manufacturing a display device according to an embodiment of the present disclosure.

FIG. 10 is a cross-sectional view of a display device at a process after the process shown in FIG. 8 according to a method of manufacturing a display device according to an embodiment of the present disclosure.

FIG. 11 is a schematic plan view of a display device at a process of FIG. 10 according to a method of manufacturing a display device according to an embodiment of the present disclosure.

FIG. 12 is a block diagram of an electronic device according to an embodiment of the present disclosure.

FIG. 13 illustrates schematic views of electronic devices according to various embodiments of the present disclosure.

### DETAILED DESCRIPTION

Embodiments of the present disclosure will be described more fully hereinafter with reference to the accompanying drawings. Like reference numerals may refer to like elements throughout the accompanying drawings.

It will be further understood that terms such as “comprise,” “include,” and “have,” when used herein, specify a presence of stated features, integers, steps, operations, elements, and/or components, but do not preclude the presence or addition of one or more other features, integers, steps, operations, elements, components, and/or groups thereof.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art, for example, within ±30%, 20%, 10% or 5% of the stated value. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

As used herein, the term “in a plan view” refers to viewing the target portion from above, while the term “in a cross-sectional view” refers to viewing a cross-section of the target portion obtained by vertically cutting through it from the side.

Embodiments of the present disclosure relate to a display device and, more particularly, to a structure and method for achieving complete and stable electrical contact in high-resolution display devices having narrow, high-aspect-ratio contact holes. In conventional metal deposition processes, insufficient step coverage within such narrow contact holes can result in incomplete electrical connections, creating defects and reducing yield.

To address the above, embodiments may provide an insulating layer that includes an opening overlapping the contact hole, along with two portions of different thicknesses that define an upper surface with a step difference. By forming a conductive material layer through a plating process that fills the contact hole, and then planarizing the top surfaces of both the conductive material and the insulating layer together by, for example, chemical mechanical polishing (CMP), a robust and continuous conductive pathway can be established.

This configuration may enable the conductive material layer to be patterned separately for each pixel without requiring an additional etching step, while also allowing for electrical contact through the contact hole to be reliably achieved. As a result, embodiments of the present disclosure support the production of high-resolution display devices with improved process efficiency and improved electrical reliability.

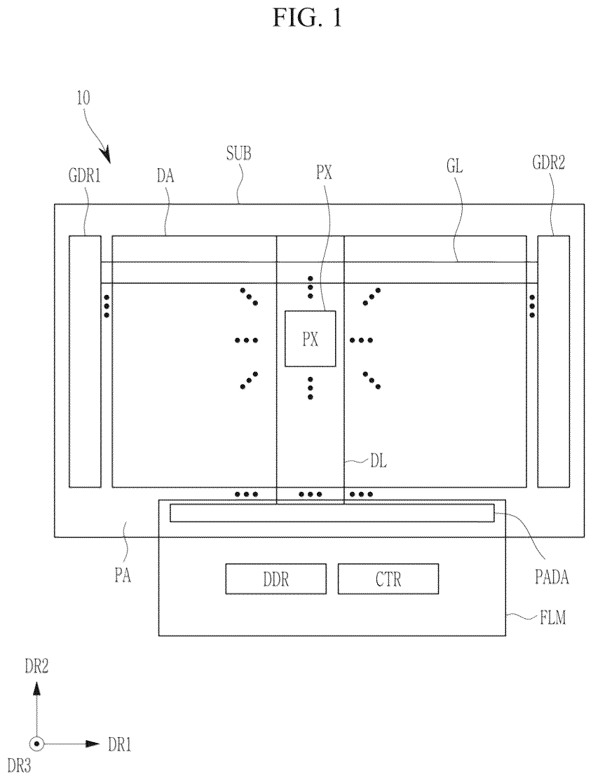

The structure of a display device according to an embodiment of the present disclosure will be described with reference to FIG. 1.

FIG. 1 is a layout view of a display device according to an embodiment of the present disclosure.

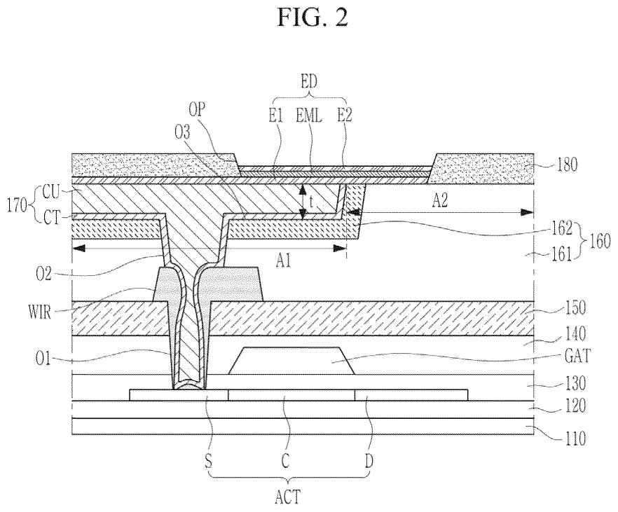

Referring to FIG. 1, a display device 10 according to an embodiment of the present disclosure may include a display area DA in which an image is displayed, and a peripheral area PA disposed outside the display area DA in which an image may not be displayed. The display device 10 includes a substrate 110 (see FIG. 2), and the display area DA and the peripheral area PA may be formed on the substrate 110. The display device 10 according to an embodiment of the present disclosure may further include gate drivers GDR1 and GDR2, a data driver DDR, and a signal controller CTR.

The substrate SUB may have various planar shapes including, for example, a polygonal shape such as a rectangle, a circular shape, an elliptical shape, an irregular shape, or the like. According to embodiments, corners of the planar shape of the outer edge of the substrate SUB may generally form sharp angles or may have round shapes. FIG. 1 shows an example in which the outer edge of the substrate SUB is generally rectangular and the corners form right angles. However, embodiments are not necessarily limited thereto. According to embodiments, “planar shape” may refer to the shape of a component when viewed in a plan view.

The display area DA may include a plurality of pixels PX, and a plurality of signal lines and a plurality of voltage lines connected to the plurality of pixels PX. Each pixel PX may include a pixel circuit portion and at least one light-emitting element. The pixel circuit portion may include a plurality of transistors and at least one capacitor.

The plurality of pixels PX may include two or more pixels configured to emit light of different colors. For example, the plurality of pixels PX may include a pixel configured to display red, a pixel configured to display green, and a pixel configured to display blue, and these pixels representing different colors from each other may emit light together to display an image of a certain color, for example, white.

The plurality of pixels PX disposed on the substrate 110 may be arranged in various forms such as, for example, a stripe arrangement, a pentile arrangement, a diamond arrangement, a mosaic arrangement, or the like.

The plurality of pixel circuit portions of the plurality of pixels PX may be arranged on the substrate SUB in a regular arrangement such as a matrix form. In the display device according to an embodiment, a plurality of pixel circuit portions forming one row and arranged in a first direction DR1 are referred to as a pixel row, and a plurality of pixel circuit portions forming one column and arranged in a second direction DR2 are referred to as a pixel column. FIG. 1 further illustrates a third direction DR3, which is orthogonal to each of the first and second directions DR1 and DR2.

The plurality of signal lines of the display area DA may include a plurality of gate lines GL and a plurality of data lines DL connected to the pixel circuit portions. The gate line GL may be connected to a gate terminal of a transistor included in the pixel circuit portion and may transmit a gate signal, and the data line DL may be connected to a source terminal or a drain terminal of a transistor included in the pixel circuit portion and may transmit a data voltage. The gate lines GL may primarily extend lengthwise in the first direction DR1 and extend to the peripheral area PA adjacent to the left or right side of the display area DA, and the data lines DL may primarily extend lengthwise in the second direction DR2 and extend to the peripheral area PA adjacent to the upper or lower side of the display area DA.

The peripheral area PA may entirely surround the display area DA. The planar shape of the boundary between the display area DA and the peripheral area PA, for example, the planar shape of the outer edge of the display area DA, may be one of various shapes such as, for example, a polygonal shape such as a rectangle, a circular shape, an elliptical shape, an irregular shape, or the like. According to an embodiment of the present disclosure, corners of the planar shape of the outer edge of the display area DA may generally form sharp angles or may have round shapes. FIG. 1 shows an example in which the outer edge of the display area DA is generally rectangular and the corners form right angles, but embodiments are not necessarily limited thereto.

The peripheral area PA may include gate drivers GDR1 and GDR2. The gate drivers GDR1 and GDR2 may be connected to the gate lines GL and may apply gate signals to the gate lines GL. The gate drivers GDR1 and GDR2 may be disposed in the peripheral area PA on the left and/or right side of the display area DA. FIG. 1 shows an example in which the first gate driver GDR1 is disposed on the left side of the display area DA and the second gate driver GDR2 is disposed on the right side. However, embodiments are not necessarily limited thereto. For example, in an embodiment, one of the first gate driver GDR1 and the second gate driver GDR2 may be omitted. The first gate driver GDR1 and the second gate driver GDR2 may include gate driving circuits configured to generate gate signals. The gate driving circuit corresponding to each pixel row may form a stage, and a plurality of stages may be sequentially disposed in the second direction DR2 in each of the first gate driver GDR1 and the second gate driver GDR2. The gate line GL of each pixel row may be connected to both the gate driving circuit of the first gate driver GDR1 and the gate driving circuit of the second gate driver GDR2 to receive gate signals, or may be connected to only one of the first gate driver GDR1 and the second gate driver GDR2. According to an embodiment of the present disclosure, the gate lines GL of the plurality of pixel rows may be alternately connected to the gate driving circuit of the first gate driver GDR1 and the gate driving circuit of the second gate driver GDR2 for each pixel row.

The peripheral area PA may further include a pad area PADA. The pad area PADA may be disposed in the peripheral area PA on the upper or lower side of the display area DA. The pad area PADA may include a plurality of conductive pads exposed without being covered by at least one insulating layer on the substrate SUB. A circuit board or a circuit film may be attached on the pad area PADA. FIG. 1 shows an example in which the display device 10 further includes a circuit film FLM attached to the pad area PADA and electrically connected to pads of the pad area PADA.

The data driver DDR and the signal controller CTR may be disposed on the circuit film FLM or a circuit board connected to the circuit film FLM, and in an embodiment, the data driver DDR and the signal controller CTR may be disposed on the substrate SUB. The data driver DDR may generate data signals and apply the data signals to the data lines DL.

The signal controller CTR may be configured to receive input image signals and input control signals transmitted from outside the signal controller CTR and process them to generate data signals and control signals configured to control operations of the gate drivers GDR1 and GDR2 and the data driver DDR. The input control signals may include, for example, a vertical synchronization signal, a horizontal synchronization signal, a main clock signal, a data enable signal, and the like. The control signals transmitted by the signal controller CTR to the data driver DDR may include, for example, a horizontal synchronization start signal, clock signals, a line latch signal, and the like, and the control signals transmitted by the signal controller CTR to the gate drivers GDR1 and GDR2 may include, for example, a vertical synchronization start signal, an output enable signal, a gate pulse signal, and the like.

A display device according to an embodiment of the present disclosure will be described with reference to FIG. 2. FIG. 2 is a cross-sectional view of a display device according to an embodiment of the present disclosure.

As shown in FIG. 2, a display device according to an embodiment of the present disclosure may include a substrate 110, a buffer layer 120 disposed on the substrate 110, a semiconductor layer ACT disposed on the buffer layer 120, a gate insulating layer 130 disposed on the semiconductor layer ACT, an interlayer insulating layer 140 disposed on the gate insulating layer 130, a gate electrode GAT disposed on the gate insulating layer 130 and overlapping the semiconductor layer ACT, and a first conductive layer 170 and a second conductive layer WIR electrically connected to the semiconductor layer ACT.

The substrate 110 may include at least one material such as, for example, glass, quartz, ceramic, sapphire, polymer resin, or the like. The substrate 110 may be a rigid substrate or a flexible substrate configured to bending, folding, rolling, or the like. The substrate SUB may be single-layered or multi-layered. The substrate 110 may be the same as the substrate SUB of FIG. 1 described above.

The buffer layer 120 may be disposed on the substrate 110 and may block impurities from the substrate 110 from flowing into the semiconductor layer ACT, which may improve characteristics of the semiconductor layer ACT. Also, the buffer layer 120 may planarize the substrate 110 to relieve stress of the semiconductor layer ACT formed on the buffer layer 120. The buffer layer 120 may have a single-layer or multi-layer structure. The buffer layer 120 may include at least one inorganic insulating material such as, for example, silicon nitride (SiNx), silicon oxide (SiOx), silicon oxynitride (SiOxNy), or the like.

The semiconductor layer ACT may include a first portion S, a channel region C, and a second portion D. The first portion S and the second portion D may be respectively disposed on both sides of the channel region C of the semiconductor layer ACT. The semiconductor layer ACT may be made of an oxide semiconductor. The oxide semiconductor may include at least one of unary metal oxides such as, for example, indium oxide (In), tin oxide (Sn), or zinc oxide (Zn), binary metal oxides such as In—Zn oxide, Sn—Zn oxide, Al—Zn oxide, Zn—Mg oxide, Sn—Mg oxide, In—Mg oxide or In—Ga oxide, ternary metal oxides such as In—Ga—Zn oxide, In—Al—Zn oxide, In—Sn—Zn oxide, Sn—Ga—Zn oxide, Al—Ga—Zn oxide, Sn—Al—Zn oxide, In—Hf—Zn oxide, In—La—Zn oxide, In—Ce—Zn oxide, In—Pr—Zn oxide, In—Nd—Zn oxide, In—Sm—Zn oxide, In—Eu—Zn oxide, In—Gd—Zn oxide, In—Tb—Zn oxide, In—Dy—Zn oxide, In—Ho—Zn oxide, In—Er—Zn oxide, In—Tm—Zn oxide, In—Yb—Zn oxide or In—Lu—Zn oxide, and quaternary metal oxides such as In—Sn—Ga—Zn oxide, In—Hf—Ga—Zn oxide, In—Al—Ga—Zn oxide, In—Sn—Al—Zn oxide, In—Sn—Hf—Zn oxide or In—Hf—Al—Zn oxide. For example, the semiconductor layer ACT may include Indium-Gallium-Zinc Oxide (IGZO) among the In—Ga—Zn oxides.

The gate insulating layer 130 may be disposed on the semiconductor layer ACT. The gate insulating layer 130 may have a single-layer or multi-layer structure. The gate insulating layer 130 may include at least one inorganic insulating material such as, for example, silicon nitride (SiNx), silicon oxide (SiOx), silicon oxynitride (SiOxNy), or the like. The gate insulating layer 130 may overlap the channel region C of the semiconductor layer ACT. The gate insulating layer 130 may be formed entirely on the substrate SUB. However, embodiments are not necessarily limited thereto. For example, in an embodiment, the gate insulating layer 130 may be patterned not to overlap the first portion S and the second portion D of the semiconductor layer ACT.

The gate electrode GAT may be disposed on the gate insulating layer 130. The gate electrode GAT may overlap the channel region C of the semiconductor layer ACT. The gate electrode GAT may include at least one metal material such as, for example, molybdenum (Mo), aluminum (Al), copper (Cu) and/or titanium (Ti). In the manufacturing process of the display device according to an embodiment, after forming the gate electrode GAT, a doping process or plasma treatment may be performed to form the first portion S and the second portion D that are distinguished from the channel region C. The portion of the semiconductor layer ACT covered by the gate electrode GAT is not doped or plasma-treated, and the portion of the semiconductor layer ACT not covered by the gate electrode GAT may be doped or plasma-treated to have the same characteristics as a conductor.

An interlayer insulating layer 140 may be disposed on the gate electrode GAT. The interlayer insulating layer 140 may be formed entirely on the substrate SUB. The interlayer insulating layer 140 may have a single-layer or multi-layer structure. The interlayer insulating layer 140 may include an inorganic insulating material and/or an organic insulating material.

A first insulating layer 150 may be disposed on the interlayer insulating layer 140. The first insulating layer 150 may be formed entirely on the substrate SUB. The first insulating layer 150 may have a single-layer or multi-layer structure. The first insulating layer 150 may include an inorganic insulating material and/or an organic insulating material. The interlayer insulating layer 140 and the first insulating layer 150 may include a first opening O1 penetrating the interlayer insulating layer 140 and the first insulating layer 150. In an embodiment, one of the interlayer insulating layer 140 and the first insulating layer 150 may be omitted.

According to embodiments, the first opening O1 may provide a conductive pathway between the semiconductor layer ACT and conductive structures formed above the first insulating layer 150. As display resolution increases, the first opening O1 typically becomes both narrower and deeper to accommodate reduced pixel sizes, which can result in challenges achieving uniform and complete deposition of conductive materials inside the opening. Embodiments of the present disclosure described herein may maintain a reliable, continuous conductive connection through the first opening O1, which may aid in preventing or reducing electrical defects and may result in stable operation of the display device.

A depth of the first opening O1 may be at least about 1.5 micrometers. Here, the depth may be a direction perpendicular to a top surface of the substrate 110.

A second insulating layer 160 may be disposed on the first insulating layer 150. The second insulating layer 160 may be formed entirely on the substrate SUB. The second insulating layer 160 may include a second opening O2 penetrating the second insulating layer 160 and a concave portion O3 connected to the second opening O2.

By forming the second opening O2 and the concave portion O3 within the second insulating layer 160, in an embodiment, the stacked contact structure can effectively bridge between the relatively deeper, narrower first opening O1 and the broader area supporting the first electrode E1. This configuration may enable the first conductive layer 170 to uniformly fill the entire passage in an embodiment, which may compensate for any incomplete coverage of the second conductive layer WIR, and promote a stable and low-resistance electrical connection from the semiconductor layer ACT to the first electrode E1. The presence of the concave portion O3 in embodiments may further facilitate planarization after plating, thereby supporting efficient patterning of the conductive structure for each pixel.

The second insulating layer 160 may have a single-layer or multi-layer structure. The second insulating layer 160 may include an inorganic insulating material and/or an organic insulating material. The second insulating layer having a multi-layer structure may include a plurality of layers distinguished according to types and/or compositions of materials included, for example, may include an organic layer 161 and an inorganic layer 162. The organic layer 161 may be disposed on the first insulating layer 150, and the inorganic layer 162 may be disposed on the organic layer 161.

A first electrode E1 may be disposed on the second insulating layer 160. For example, the first electrode E1 may be disposed on the inorganic layer 162 of the second insulating layer 160. The first electrode E1 may be formed in a single layer or multiple layers, and may include at least one metal and/or at least one transparent conductive oxide. The first electrode E1 may include at least one metal such as, for example, silver (Ag), lithium (Li), calcium (Ca), aluminum (Al), magnesium (Mg), and/or gold (Au), or may include at least one transparent conductive oxide (TCO) such as, for example, indium tin oxide (ITO) and/or indium zinc oxide (IZO). For example, the first electrode E1 may have a triple-layer structure of indium tin oxide (ITO)/silver (Ag)/indium tin oxide (ITO).

A third insulating layer 180 may be disposed on the first electrode E1. The third insulating layer 180 may also be referred to as a partition wall or a pixel insulating layer. The third insulating layer 180 may include at least one organic insulating material such as, for example, general-purpose polymers like Polymethylmethacrylate (PMMA) or Polystyrene, polymer derivatives having phenolic groups, acrylic polymers, imide polymers, polyimide, acrylic polymers, siloxane polymers, or the like. A pixel opening OP may be formed in the third insulating layer 180, and the pixel opening OP may overlap the first electrode E1.

A light-emitting layer EML may be disposed within the pixel opening OP of the third insulating layer 180. The light-emitting layer EML may include at least one material layer that inherently emits light of basic colors such as, for example, the primary colors red, green, and blue. The light-emitting layer EML may have a structure in which a plurality of material layers emitting light of different colors are stacked. Although the light-emitting layer EML is shown as being disposed only within the pixel opening OP, embodiments are not necessarily limited thereto. For example, in an embodiment, the light-emitting layer EML may be disposed not only within the pixel opening OP but also on the third insulating layer 180. For example, the light-emitting layer EML may be disposed entirely on the substrate SUB in some embodiments.

A second electrode E2 may be disposed on the light-emitting layer EML and the third insulating layer 180. The second electrode E2 may include at least one reflective metal such as, for example, calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), lithium (Li), calcium (Ca), and/or at least one transparent conductive oxide (TCO) such as, for example, indium tin oxide (ITO), indium zinc oxide (IZO).

The first electrode E1, the light-emitting layer EML, and the second electrode E2 form a light-emitting diode ED. Here, the first electrode E1 may be an anode which is a hole injection electrode, and the second electrode E2 may be a cathode which is an electron injection electrode. However, embodiments are not necessarily limited thereto, and according to a driving method of the organic light emitting display device, the first electrode E1 may become a cathode and the common electrode E2 may become an anode.

Holes and electrons are respectively injected into the light-emitting layer EML from the first electrode E1 and the common electrode E2, and light emission occurs when excitons formed by the combination of the injected holes and electrons fall from an excited state to a ground state.

A display device according to an embodiment of the present disclosure may include a first conductive layer 170 disposed in the first opening O1, the second opening O2, and the concave portion O3 below the first electrode E1, and the first opening O1, the second opening O2, and the concave portion O3 may be filled by the first conductive layer 170.

Also, a display device according to an embodiment of the present disclosure may further include a second conductive layer WIR, and the first conductive layer 170 may be disposed on and contact the second conductive layer WIR.

The second conductive layer WIR may be disposed on and contact an inner wall of the first opening O1 penetrating the interlayer insulating layer 140 and an inner wall of the first insulating layer 150, and a top surface of the first insulating layer 150. The second conductive layer WIR may include at least one of, for example, a source electrode, a drain electrode, and wiring connected to a transistor. The source electrode and the drain electrode may be respectively connected to at least one of the first portion S and the second portion D of the semiconductor layer ACT.

The second conductive layer WIR may include at least one of metal materials such as, for example, molybdenum (Mo), aluminum (Al), copper (Cu) and/or titanium (Ti), and alloys of two or more metals, and may include single layer or multiple layers. For example, the second conductive layer WIR may have a triple-layer structure such as Ti/Al/Ti, but is not necessarily limited thereto.

Referring to a comparative example, the second conductive layer WIR may be formed on the interlayer insulating layer 140 and the first insulating layer 150 using, for example, a deposition process. During this formation process, the second conductive layer WIR may also be deposited on the inner wall of the first opening O1 penetrating through the interlayer insulating layer 140 and the inner wall of the first insulating layer 150. As the resolution of the display device increases, the width of the first opening O1 generally becomes narrower and its depth deeper, which can result in non-uniform deposition of the second conductive layer WIR inside the first opening O1. For example, an overhang phenomenon in which materials of the second conductive layer WIR are excessively accumulated may occur around edges of the first opening O1. As a result, materials of the second conductive layer WIR may not sufficiently spread on the inner walls of the first opening O1, and materials (for example, metal) of the second conductive layer WIR may be insufficiently deposited on a bottom surface of the first opening O1 disposed adjacent to the semiconductor layer ACT and edges of the bottom surface. For example, the second conductive layer WIR may fail to sufficiently spread along the inner walls or reach the bottom surfaces of the first opening O1 near the semiconductor layer ACT. When the second conductive layer WIR is not uniformly deposited on the inner walls of the first opening O1 and a top surface of the semiconductor layer ACT, contact between the second conductive layer WIR and the semiconductor layer ACT may be incomplete, and electrical defects may occur.

In contrast to the comparative example, in the display device according to an embodiment of the present disclosure, the first conductive layer 170 is filled on the second conductive layer WIR to stably connect the semiconductor layer ACT and the second conductive layer WIR. Even if the second conductive layer WIR is not uniformly deposited on inner walls of the first opening O1, the first conductive layer 170 may be filled in empty spaces where metal is not deposited to electrically connect the second conductive layer WIR and the semiconductor layer ACT. For example, according to a method of forming the first conductive layer 170 different from the second conductive layer WIR as described further below, electrical connection from the first electrode E1 to the semiconductor layer ACT can be sufficiently achieved.

For example, according to embodiments, the first conductive layer 170 may additionally compensate for non-uniformities or voids created during patterning or etching processes associated with forming the first opening O1 or the second opening O2. In this manner, the first conductive layer 170 can bridge discontinuities or thin regions of the second conductive layer WIR, which may improve the electrical stability and long-term reliability of the pixel circuit. Further, the plated nature of the first conductive layer 170 may enable a more complete filling of complex structures within the stacked openings, including the concave portion O3, which may support robust contact between the semiconductor layer ACT and the first electrode E1 across a wide variety of manufacturing conditions.

Hereinafter, a positional relationship between the first conductive layer 170 and the second insulating layer 160 including the concave portion O3 will be described in detail.

The first opening O1, the second opening O2, and the concave portion O3 are connected to each other as one passage filled by the first conductive layer 170, and may be filled by the first conductive layer 170. Therefore, the first conductive layer 170 is disposed in the concave portion O3 and may overlap the concave portion O3 in a plan view. The inorganic layer 162 is also disposed in the concave portion O3 and may overlap the concave portion O3 in a plan view.

The second insulating layer 160 may include a first region A1 overlapping the first conductive layer 170 in a plan view and a second region A2 connected to the first region A1. A step difference t may exist between a top surface of the first region A1 and a top surface of the second region A2, the concave portion O3 may be formed by the step difference t, and the first conductive layer 170 may be filled above the first region A1.

The top surface of the second region A2 of the second insulating layer 160 and the top surface of the first conductive layer 170 may together form a single flat surface. This is because the first conductive layer 170 is formed by electroplating a metal material such as copper in the first opening O1, the second opening O2, and the concave portion O3 to form a conductive layer, and then the conductive layer and material layers constituting the second insulating layer 160 are polished together to form the flat surface.

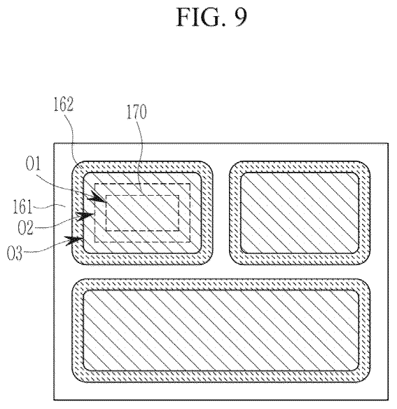

Also, as described above, the second insulating layer 160 may include the organic layer 161 and the inorganic layer 162, and the top surface of the second region A2 of the second insulating layer 160 may include a planar top surface of the inorganic layer 162 near a boundary between the first region A1 and the second region A2, and a planar top surface of the organic layer 161. In a plan view, the planar top surface of the inorganic layer 162 may be disposed between the planar top surface of the first conductive layer 170 and the planar top surface of the organic layer 161. This is shown in FIG. 9 to be described further below.

The first conductive layer 170 and the second insulating layer 160 may have one planar top surface, and the first electrode E1 may be formed over and across the planar top surface of the first conductive layer 170 and the top surface of the second insulating layer 160. The top surface of the first conductive layer 170 and the first electrode E1 may contact each other. Therefore, as described above, not only the second conductive layer WIR and the semiconductor layer ACT are stably connected to each other through the first conductive layer 170, but also the first electrode E1 and the semiconductor layer ACT may be electrically connected to each other through the first conductive layer 170.

The first conductive layer 170 may include a first layer CT and a second layer CU disposed on the first layer CT. As a result, the first conductive layer 170 can efficiently fill in the first opening O1, the second opening O2, and the concave portion O3. For example, in an embodiment, the first conductive layer 170 may fill an entirety of the first opening O1, the second opening O2, and the concave portion O3. The first layer CT may contact the inner wall of the second opening O2 and the inner wall of the concave portion O3. The first layer CT may have a different material composition from the second layer CU, for example, the first layer CT may include titanium, and the second layer CU may include copper. After coating the first layer CT including titanium, the second layer CU is formed by electroplating a metal material including copper on the first layer CT. As a result, in embodiments, growth characteristics of copper may be improved. The first layer CT including titanium may promote initial nucleation of copper ions and enable uniform deposition, so that growth of copper in the electroplating process can be performed more efficiently. The first layer CT may be formed by coating a material including titanium by, for example, a sputtering method.

The display device according to an embodiment of the present disclosure includes the first conductive layer 170 disposed in the first opening O1, the second opening O2, and the concave portion O3 below the first electrode E1. As a result, the first electrode E1 and the semiconductor layer ACT can be electrically connected to each other through the first conductive layer 170. Also, by connecting the second conductive layer WIR and the semiconductor layer ACT to each other through the first conductive layer 170, a stable connection structure may be secured, and contact defects between the second conductive layer WIR and the semiconductor layer ACT can be prevented. As a result, a high-resolution display device may be provided.

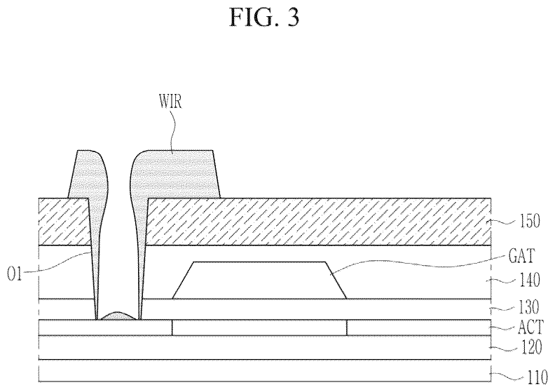

FIGS. 3 to 8 are schematic cross-sectional views illustrating sequential processes of a method of manufacturing a display device according to an embodiment of the present disclosure.

FIG. 3 is a cross-sectional view showing a state where a second conductive layer is formed after forming a first insulating layer including a first opening.

A manufacturing method of a display device according to an embodiment of the present disclosure may include forming a substrate 110, forming a semiconductor layer ACT on the substrate 110, and forming a first insulating layer 150 including a first opening O1 on the semiconductor layer ACT. Referring to FIG. 3, the first opening O1 may penetrate the interlayer insulating layer 140 and the first insulating layer 150, and a second conductive layer WIR is formed on the inner wall of the first opening O1 and a top surface of the first insulating layer 150.

Referring to a comparative example, during the formation process of the second conductive layer WIR, the second conductive layer WIR may not be uniformly deposited due to the structure of the narrow first opening O1. For example, an overhang phenomenon in which the material of the second conductive layer WIR is excessively accumulated on the sidewall portions of the first opening O1, for example, on the edge of the first opening O1 may occur. As a result, the material of the second conductive layer WIR may not sufficiently spread on the inner wall of the first opening O1, and as a result, the metal of the second conductive layer WIR may not be deposited or may be insufficiently deposited on the bottom surface of the first opening O1 disposed adjacent to the semiconductor layer ACT and on the edge of the bottom surface of the first opening O1. Thus, in the comparative example, the second conductive layer WIR is not uniformly deposited on the inner wall of the first opening O1, contact between the second conductive layer WIR and the semiconductor layer ACT becomes incomplete, and electrical defects may occur.

In contrast to the comparative example, to overcome issues of non-uniform metal deposition within the first opening O1 described above, embodiments of the present disclosure may utilize a conductive filling technique that can reliably establish continuity between the second conductive layer WIR and the semiconductor layer ACT. For example, plating the first conductive layer 170 to fill remaining voids or incomplete areas of the second conductive layer WIR may enable a stable, uniform, and low-resistance contact path, even in high-resolution devices having narrow and deep openings.

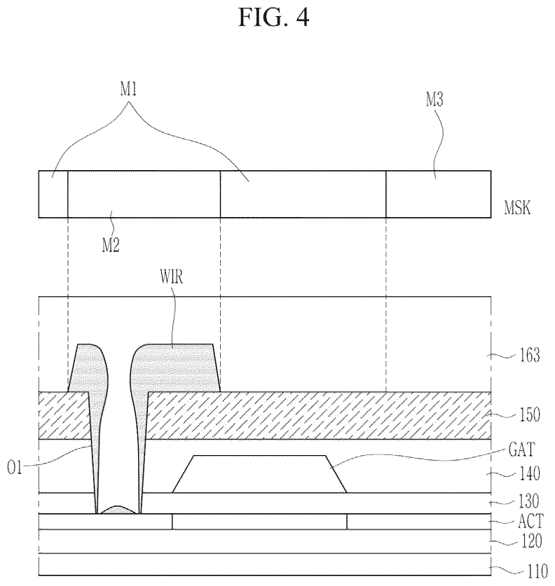

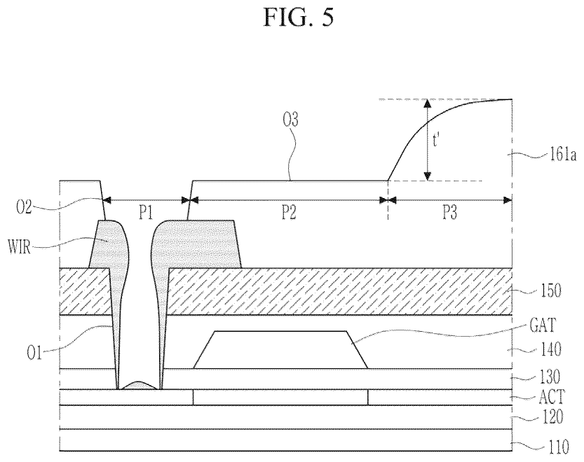

FIGS. 4 and 5 are cross-sectional views illustrating an operation of forming a second insulating layer on the second conductive layer and the first insulating layer.

A method of manufacturing a display device according to an embodiment of the present disclosure may include forming a first material layer 161a including a second opening O2 overlapping the first opening O1 and a concave portion O3 on the first insulating layer 150. The operation of forming the first material layer 161a may include performing a photolithography process. For example, the operation of forming the first material layer 161a may include applying a first material 163 on the first insulating layer 150, and exposing the first material 163 using a photomask MSK.

According to embodiments of the present disclosure, by incorporating the second opening O2 and the concave portion O3 in the second insulating layer 160, the overall contact structure may support more effective filling by the first conductive layer 170 and also result in improved planarization. This arrangement may aid in the transition between the relatively small first opening O1 and the larger area suitable for the pixel electrode, which may improve the manufacturability and electrical stability of the display device.

The first material layer 161a may include an organic material. The photomask MSK may include a first portion M1 overlapping the first opening O1 to be formed, a second portion M2 adjacent to the first portion M1, and a third portion M3 adjacent to the second portion M2.

Referring to FIG. 5 together with FIG. 4, the first material layer 161a that has undergone the photolithography process through the photomask MSK may include a first zone P1 corresponding to the first portion M1 of the photomask MSK, a second zone P2 corresponding to the second portion M2 of the photomask MSK, and a third zone P3 corresponding to the third portion M3 of the photomask MSK.

The second opening O2 may be formed in the first zone P1. The first portion M1 of the photomask MSK may be a light-blocking portion for the second opening O2 to be formed. If the first portion M1 is a light-blocking portion, a photosensitive solution used in the photolithography process may be a negative photosensitive solution. However, embodiments are not necessarily limited thereto. For example, in an embodiment, the first portion M1 may be a light-transmitting portion, and a photosensitive solution used in the photolithography process may be a positive photosensitive solution.

The concave portion O3 may be formed in the second zone P2. The second portion M2 of the photomask MSK may be a halftone portion. Since the second portion M2 of the photomask MSK is a halftone portion in an embodiment, it transmits only a portion of light so that only a portion of the first material 163 may remain.

The amount of the first material 163 remaining in the third zone P3 may be greater than the amount of the first material 163 remaining in the second zone P2. In an embodiment, the third portion M3 of the photomask MSK may be configured to transmit more light than the other portions if the first portion M1 is a light-blocking portion. Conversely, in an embodiment, if the first portion M1 of the mask is a light-transmitting portion, then the third portion M3 may transmit less light than the other portions among the first portion M1, the second portion M2, and the third portion M3.

Accordingly, because amounts of the first material 163 remaining after the photoresist process are different in the second zone P2 and the third zone P3, a step difference t′ is formed in the first material layer 161a between the second zone P2 and the third zone Pe.

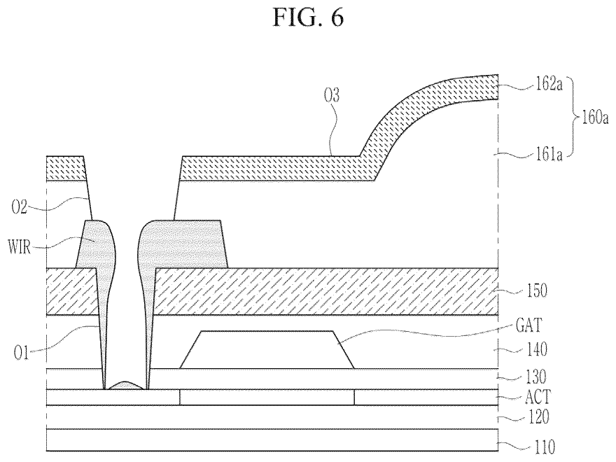

Referring to FIG. 6, a second material layer 162a is formed on the first material layer 161a. An insulating material layer 160a is formed by forming the second material layer 162a on the first material layer 161a. The insulating material layer 160a may include the first material layer 161a and the second material layer 162a.

The second material layer 162a may be formed by a photolithography process. In this case, the second material layer 162a may include an inorganic material. An opening may also be formed in the second material layer 162a at a portion overlapping the first opening O1, and the two continuous openings may be together referred to as the first opening O1.

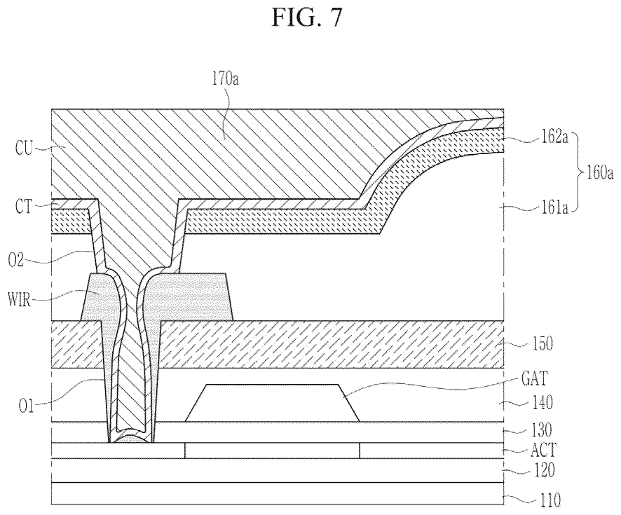

FIG. 7 is a cross-sectional view showing a state after a conductive material layer 170a is formed. Hereinafter, an operation of forming the conductive material layer 170a will be described with reference to FIG. 7.

A conductive material layer 170a is formed on the insulating material layer 160a.

The operation of forming the conductive material layer 170a may include plating a conductive material. The operation of plating the conductive material may be an electroplating operation.

The electroplating operation may be an operation of filling an electrolyte solution including metal ions in the first opening O1, the second opening O2, and the concave portion O3, and then applying a voltage to the electrolyte solution and reducing the metal ions to deposit a conductive material on the inner walls of the first opening O1, the second opening O2, and the concave portion O3. The conductive material may include copper, and the electroplating step may include an operation of reducing copper ions.

In the operation of forming the conductive material layer 170a, the conductive material layer 170a may include a first layer CT and a second layer CU disposed on the first layer CT. The first layer CT may contact the inner wall of the second opening O2 and the inner wall of the concave portion O3.

The first layer CT may include titanium, and the second layer CU may include copper. If the second layer CU is formed by electroplating a conductive material including copper on the first layer CT including titanium, growth characteristics of copper may be improved. The first layer CT including titanium may promote initial nucleation of copper ions and enable uniform deposition of copper. As a result, growth of copper in the electroplating process can be performed more efficiently. The first layer CT may be formed by coating a material including titanium on surfaces of the first opening O1, the second opening O2, and the concave portion O3 by a sputtering method performed before the electroplating operation using copper.

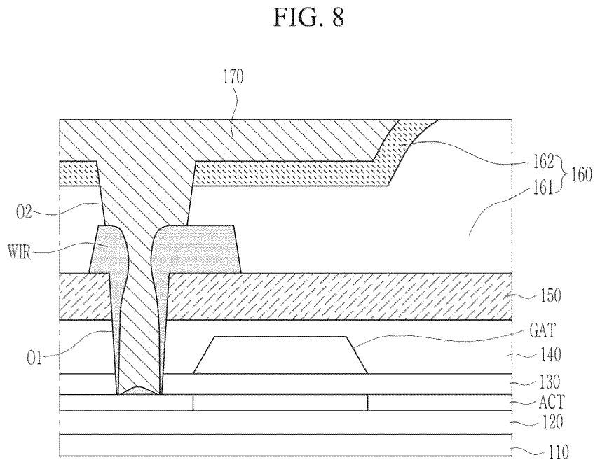

FIG. 8 is a cross-sectional view showing a state after polishing top surfaces of the conductive material layer 170a and the insulating material layer 160a to be flat. FIG. 9 is a plan view showing a state after polishing top surfaces of the conductive material layer 170a and the insulating material layer 160a to be flat.

Hereinafter, an operation of polishing top surfaces of the conductive material layer 170a and the insulating material layer 160a to be flat will be described with reference to FIGS. 8 and 9 together with FIG. 6.

A method of manufacturing a display device according to an embodiment of the present disclosure may include an operation of polishing top surfaces of the conductive material layer 170a and the insulating material layer 160a to be flat. For example, the top surfaces of the conductive material layer 170a and the insulating material layer 160a may be planarized through a chemical mechanical polishing (CMP) process.

When the top surfaces of the conductive material layer 170a and the insulating material layer 160a are planarized, the first conductive layer 170 and the second insulating layer 160 may be formed. The first conductive layer 170 may have a form patterned to be separated for each pixel.

Referring to FIG. 9, the first conductive layer 170 may be formed to overlap the first opening O1, the second opening O2, and the concave portion O3 in a plan view. In the plan view, the inorganic layer 162 may surround the first conductive layer 170, and the organic layer 161 may surround the inorganic layer 162. The first conductive layer 170, the organic layer 161, and the inorganic layer 162 may together form a single flat surface in the plan view.

According to embodiments, the planar configuration in the plan view described above may facilitate reliable electrical contact across the pixel region (e.g., the entire pixel region), while also reducing variation in step height that could otherwise disrupt pixel uniformity or color consistency. As display resolutions continue to increase, such a planarized conductive layout may support tighter pixel packing without sacrificing electrical connection stability or manufacturing yield.

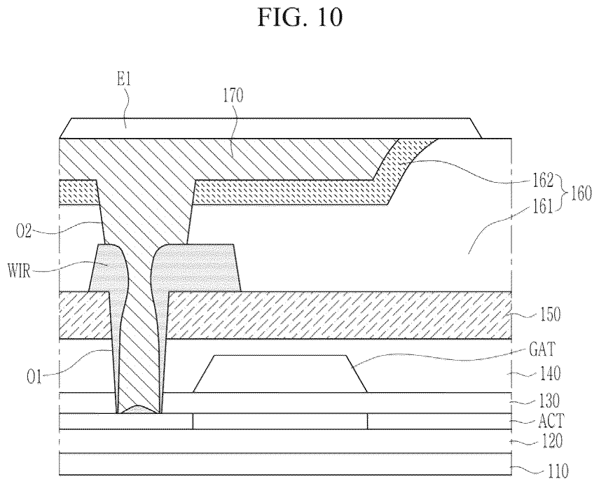

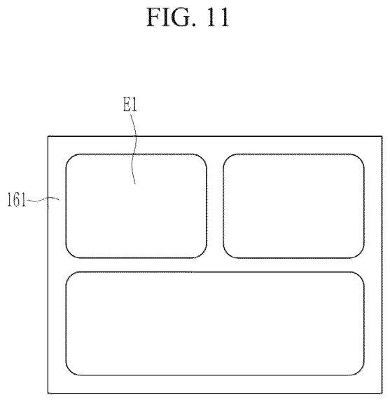

FIG. 10 is a cross-sectional view showing a state after the first electrode E1 is formed. FIG. 11 is a plan view showing a state after the first electrode E1 is formed.

A method of manufacturing a display device according to an embodiment of the present disclosure may include an operation of depositing a first electrode E1 on the first conductive layer 170 and the second insulating layer 160 after the first conductive layer 170 and the second insulating layer 160 are formed.

Referring to FIG. 11 together with FIG. 10, the operation of depositing the first electrode E1 may include forming the first electrode E1 to completely cover the first conductive layer 170 in a plan view. Thereafter, the first electrode E1 and the semiconductor layer ACT may be electrically connected to each other through the first conductive layer 170.

The method of manufacturing a display device according to an embodiment of the present disclosure can efficiently fill the conductive material in the first opening O1, the second opening O2, and the concave portion O3 connected to the semiconductor layer ACT by forming the conductive material layer 170a by a plating method. In addition, by forming the first material layer 161a to have a step difference, the first conductive layer 170 may be formed only by a planarization polishing process after the conductive material layer 170a is formed. Accordingly, the first conductive layer 170 can be patterned to be separated for each pixel without any additional etching process, allowing for a display device to be manufactured by an efficient and economical method.

By implementing the plating-based formation of the first conductive layer 170 together with the step-difference insulating structure, embodiments of the present disclosure may reduce the risk of defects from incomplete contact or insufficient step coverage, which may be beneficial for high-resolution and high-density pixel arrangements. The configuration provided by embodiments may support consistent electrical performance across the display panel while streamlining the manufacturing process and improving production yield.

Hereinafter, an electronic device to which the display device can be applied will be described.

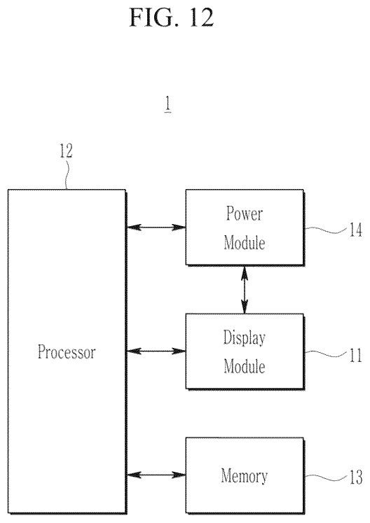

FIG. 12 is a block diagram of an electronic device according to an embodiment of the present disclosure.

Referring to FIG. 12, an electronic device 1 according to an embodiment of the present disclosure may include a display module 11, a processor 12, a memory 13, and a power module 14. The display module 11 may include the display device accordingly to various embodiments as described above.

The processor 12 may include at least one of, for example, a central processing unit (CPU), an application processor (AP), a graphic processing unit (GPU), a communication processor (CP), an image signal processor (ISP), and a controller.

Data information utilized for operations of the processor 12 or the display module 11 may be stored in the memory 13. When the processor 12 executes an application stored in the memory 13, image data signals and/or input control signals are transmitted to the display module 11, and the display module 11 may process the received signals to output image information through a display screen. The display module 11 may include the display device 10 according to embodiments described above.

The power module 14 may include a power supply module such as, for example, a power adapter or battery device, and a power conversion module that converts power supplied by the power supply module to generate power utilized for operation of the electronic device 1.

At least one of the respective components of the electronic device 1 described above may be included in the display device according to embodiments described above. Also, some of individual modules functionally included in one module may be included in the display device and others may be provided separately from the display device. For example, the display device may include the display module 11, and the processor 12, the memory 13, and the power module 14 may be provided in the form of other devices in the electronic device 1 rather than the display device.

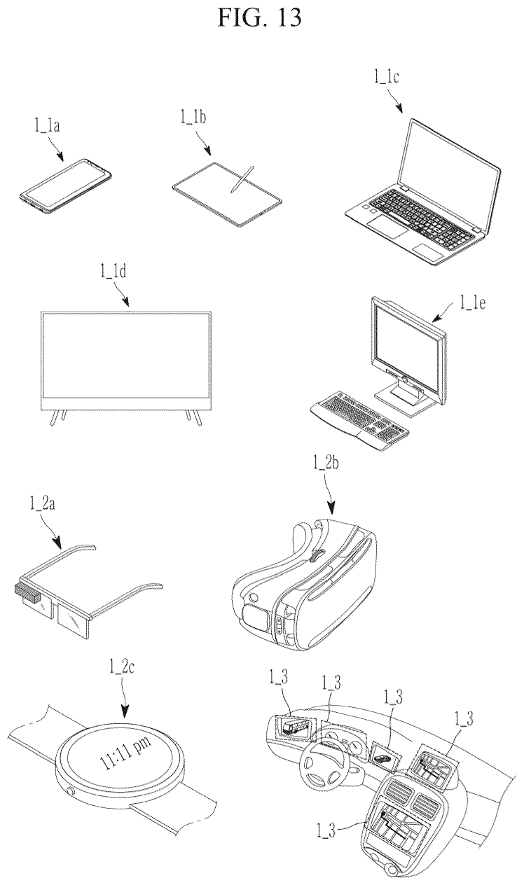

FIG. 13 illustrates schematic views of electronic devices according to various embodiments of the present disclosure.

Referring to FIG. 13, various electronic devices 1 to which display devices according to embodiments are applied may include not only electronic devices for image display such as a smartphone 1_1a, a tablet computer 1_1b, a laptop/notebook computer 1_1c, a TV 1_1d, and a computer monitor 1_1e, but also wearable electronic devices including display modules such as smart glasses 1_2a, a head mount display 1_2b, and a smart watch 1_2c, and vehicle electronic devices 1_3 including display modules such as an instrument panel of automobiles, a center fascia, a center information display (CID) disposed on the dashboard, the rearview mirror, and the like.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. In embodiments, each block, unit and/or module may be implemented by dedicated hardware, or as a combination of dedicated hardware to perform some functions and a processor (e.g., one or more programmed microprocessors and associated circuitry) to perform other functions.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a substrate;
a semiconductor layer disposed on the substrate;
a first insulating layer disposed on the semiconductor layer, the first insulating layer including a first opening;
a second insulating layer disposed on the first insulating layer, the second insulating layer including a second opening and a concave portion;
a first electrode disposed on the second insulating layer;
a third insulating layer disposed on the first electrode, the third insulating layer including a pixel opening;
a light-emitting layer disposed in the pixel opening; and
a first conductive layer disposed in the first opening, the second opening, and the concave portion below the first electrode.

2. The display device of claim 1, wherein
the first opening, the second opening and the concave portion are filled by the first conductive layer.

3. The display device of claim 2, wherein
the first conductive layer comprises copper.

4. The display device of claim 2, further comprising:
a second conductive layer disposed in the first opening.

5. The display device of claim 4, wherein
the first electrode is electrically connected to the semiconductor layer through the first conductive layer.

6. The display device of claim 4, wherein
the first conductive layer comprises a first layer and a second layer disposed on the first layer, and
the first layer contacts an inner wall of the second opening and an inner wall of the concave portion.

7. The display device of claim 6, wherein
the first layer comprises titanium, and
the second layer comprises copper.

8. The display device of claim 2, wherein
the second insulating layer comprises an organic layer and an inorganic layer,
the organic layer is disposed on the first insulating layer, and
the inorganic layer is disposed on the organic layer.

9. The display device of claim 8, wherein
the inorganic layer is disposed in the concave portion and overlaps the concave portion in a plan view.

10. The display device of claim 1, wherein
the second insulating layer comprises a first region overlapping the first conductive layer in a plan view, and a second region connected to the first region, and
a step difference exists between a top surface of the first region and a top surface of the second region.

11. The display device of claim 10, wherein
the top surface of the second region of the second insulating layer and a top surface of the first conductive layer form a single flat surface.

12. The display device of claim 11, wherein
the second insulating layer comprises an organic layer and an inorganic layer,
the top surface of the second region of the second insulating layer comprises a planar top surface of the inorganic layer and a planar top surface of the organic layer, and
in a plan view, the planar top surface of the inorganic layer is between the planar top surface of the first conductive layer and the planar top surface of the organic layer.

13. The display device of claim 1, wherein
a depth of the first opening is at least about 1.5 micrometers.

14. A method of manufacturing a display device, comprising:
forming a substrate;
forming a semiconductor layer on the substrate;
forming a first insulating layer including a first opening on the semiconductor layer;
forming a first material layer including a second opening overlapping the first opening and a concave portion on the first insulating layer;
forming a conductive material layer filling the first opening, the second opening, and the concave portion; and
polishing a top surface of the conductive material layer and a top surface of an insulating material layer including the first material layer to be flat.

15. The method of claim 14, wherein
forming the first material layer comprises applying a first material on the first insulating layer, and exposing the first material using a photomask,
the photomask comprises a first portion overlapping the first opening, a second portion adjacent to the first portion, and a third portion adjacent to the second portion, and
the second portion is a halftone portion that allows only a portion of light to pass through the halftone portion.

16. The method of claim 15, wherein
the second opening is formed in a region corresponding to the first portion, and
the concave portion is formed in a region corresponding to the second portion.

17. The method of claim 14, wherein
forming the conductive material layer comprises plating a conductive material.

18. The method of claim 17, wherein
the conductive material comprises copper.

19. The method of claim 14, wherein
the conductive material layer comprises a first layer and a second layer disposed on the first layer,
the first layer comprises titanium, and
the second layer comprises copper.

20. An electronic device, comprising:
a processor; and
a display device connected to the processor,
wherein the display device comprises:
a substrate;
a semiconductor layer disposed on the substrate;
a first insulating layer disposed on the semiconductor layer, the first insulating layer including a first opening;
a second insulating layer disposed on the first insulating layer, the second insulating layer including a second opening and a concave portion;
a first electrode disposed on the second insulating layer;
a third insulating layer disposed on the first electrode, the third insulating layer including a pixel opening;
a light-emitting layer disposed in the pixel opening; and
a first conductive layer disposed in the first opening, the second opening, and the concave portion below the first electrode.
